(19) United States
(12) Patent Application Publication
(10) Pub. No.: US 2007/0231991 A1
(43) Pub. Date: Oct. 4, 2007

(54) Semiconductor memory device and method of operating a semiconductor memory device

(76) Inventors: Josef Willer, Riemerling (DE); Nicolas Nagel, Dresden (DE); Thomas Mikolajick, Dresden (DE); Karl-Heinz Kuesters, Boxdorf (DE)

Correspondence Address: SLATER & MATSIL LLP, 17950 PRESTON ROAD, SUITE 1000, DALLAS, TX, 75252, US

(21) Appl. No.: 11/396,398

(22) Filed: Mar. 31, 2006

(51) Int. Cl. H01L 21/8238

(52) U.S. Cl. 438/217

(57) ABSTRACT

A semiconductor memory device includes a channel region, a gate electrode adjacent the channel region, and a charge-trapping layer between the channel region and the gate electrode. A voltage is applied between the gate electrode and the channel region to cause a first current of a first kind of charge carriers from the channel region to move into the charge-trapping layer and to cause a second current of a second kind of charge carriers from the gate electrode to move into the charge-trapping layer, until the value of the second current is at least half the amount of the first current value.

### TECHNICAL FIELD

The present invention concerns semiconductor memory devices and an operating method for semiconductor memory devices having large storage capacity.

### BACKGROUND

Charge-trapping memory devices are preferable alternatives to floating-gate EEPROM devices. They can be used especially favorably in chip cards that are based on flash memories. The charge-trapping memory cells are programmed by an introduction of charge carriers, e.g., electrons, into the charge-trapping layer, where they are trapped and permanently change the threshold voltage of the transistor structure of the memory cell. If the charge carriers that are to be trapped are sufficiently accelerated in the channel to acquire enough kinetic energy, the resulting so-called hot charge carriers, especially CHE (channel hot electrons), can be injected into the charge-trapping layer by means of a relatively low voltage that is applied between the gate electrode and the channel. Especially SONOS memory cells having oxide-nitride-oxide layer sequences as storage medium, are usually programmed by channel hot electron injection.

Charge-trapping memory cells of a special type of so-called NROM cells, which are provided with a relatively thick lower boundary layer in the memory layer sequence, can be used to store bits of information at the source/drain regions on both channel ends below the respective gate edges. The programmed cell is read in reverse mode to achieve a sufficient two-bit separation. Erasure is performed by hot hole injection.

The charge carriers have to pass a boundary layer between the charge-trapping layer and the electrically conductive material from which they originate, especially the semiconductor material of the channel region. This can be achieved by a tunneling process known as Fowler-Nordheim tunneling. This process is generated by an application of a voltage between the channel region and the gate electrode to draw charge carriers of low energy from the channel region through the lower boundary layer into the charge-trapping layer.

The charge-trapping memory cell can be erased by introducing charge carriers of opposite sign into the charge-trapping layer. If the memory cell is programmed with electrons, channel hot holes can be injected from the channel to erase the cell, if an accelerating voltage is applied between the source/drain regions. The positive charge of the holes compensates at least partly the negative charge of the trapped electrons and restores the original erased state of the memory cell. This way of erasure requires large currents if a large array of memory cells is erased simultaneously.

An erasure can also be effected by Fowler-Nordheim tunneling of holes from the channel into the charge-trapping layer, if a negative voltage is applied to the gate electrode. The drawback of this mode of erasure is the tunneling of electrons from the electrode into the charge-trapping layer so that the charge is not completely removed from the charge-trapping layer.

This effect is primarily relevant if a high negative voltage is applied to the gate electrode in order to speed up the erasing process. As the charge in the charge-trapping layer is continually reduced, the decreasing negative potential in the charge-trapping layer allows more and more negative charge carriers to pass into the charge-trapping layer from the gate electrode. Thus, a state of saturation is attained, in which a residual charge is present in the charge-trapping layer, which can no longer be reduced. A lower potential difference may be applied between the gate electrode and the channel, but this will result in a slower erasing process; a prolonged erasure may cause some kind of overerasure. This means that the threshold voltages of the transistors acquire a wide range of negative values, depending on the erasing time, so that finally there are different states of the memory cells that have been erased in common.

An erased state that is well defined requires a small distribution of the threshold voltages so that the threshold voltages of all memory cells belonging to the erased sector lie within the same narrow range. The problem is aggravated by the fact that a lower boundary layer between the semiconductor material of the channel region and the charge-trapping layer preferably has a minimal thickness of about 3 nm in order to guarantee a good data retention.

### SUMMARY OF THE INVENTION

The threshold voltage of a charge-trapping device having at least a channel region, a gate electrode controlling an electric field within the channel region and a charge-trapping layer between the channel region and the gate electrode is changed by applying a voltage between the gate electrode and the channel region. This causes a first current of a first kind of charge carriers from the channel region to move into the charge-trapping layer and to cause a second current of a second kind of charge carriers from the gate electrode to move into the charge-trapping layer. The second current is stopped when the value of the second current is at least half the amount of the first current value.

The semiconductor memory device includes a channel region, a gate electrode controlling an electric field within the channel region, and a charge-trapping layer between the channel region and the gate electrode. Operating circuitry provides a voltage between the gate electrode and the channel region. The voltage is selected to cause a first current of a first kind of charge carriers from the channel region to move into the charge-trapping layer and to cause a second current of a second kind of charge carriers from the gate electrode to move into the charge-trapping layer, until the value of the second current is at least half the amount of the first current value.

These and other aspects of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross section of an embodiment of a charge-trapping memory cell according to the invention;

FIG. 2, consisting of FIGS. 2a and 2b, shows a diagram of different charge distributions in a programmed multi-bit memory cell;

FIG. 3 shows a diagram representing a comparison of changes of the threshold voltage over time for erasing voltages including voltages according to the present invention;

FIG. 4 shows a diagram representing the change of the threshold voltage over time for different initial values of the threshold voltage in accordance with the present invention; and

FIG. 5 shows a schematic view of a memory that is divided in partially programmed sectors used in conjunction with the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

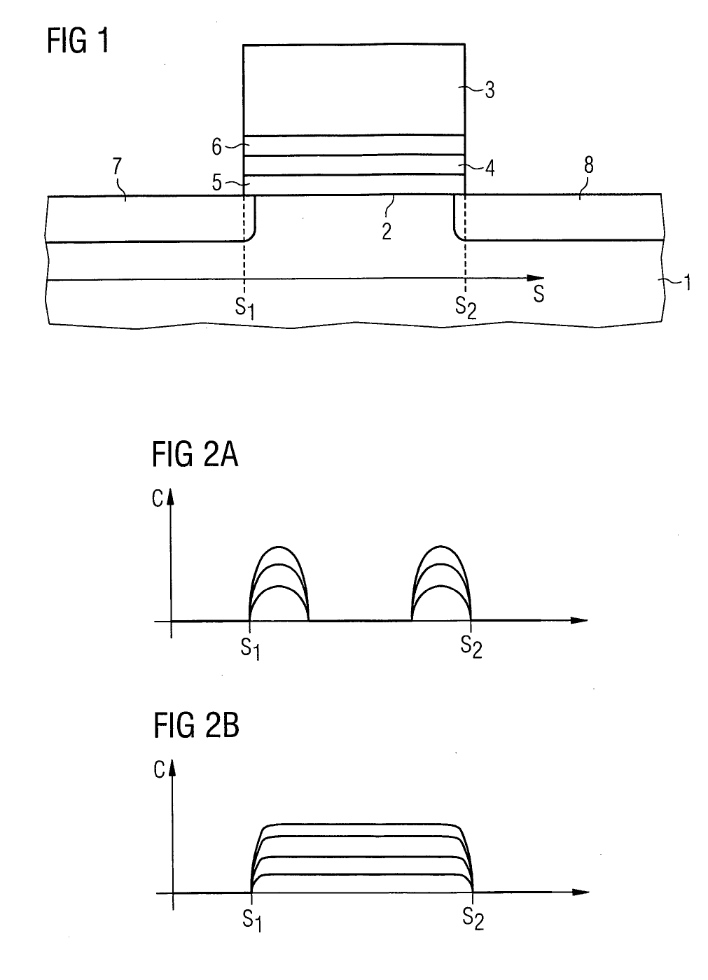

FIG. 1 shows a cross section of an example of a charge-trapping memory cell. At a main surface of a semiconductor substrate 1, a channel region 2 is located, which is controlled by a gate electrode 3. The channel region is preferably located in an inner well, which is arranged in an outer well, which is formed in the substrate. The substrate, the outer well, and the inner well have alternating signs of conductivity. In the example of an n-channel transistor structure of the memory cell, the inner well is p-doped, the outer well is n-doped, and the substrate is provided with a basic p-conductivity. The inner and outer wells are preferably limited to confined regions of the substrate. In this manner, a number of triple well structures are present, which enable an erasure of only a part or sector of the memory cell array in a single erasing process. A charge-trapping layer 4 of dielectric material substitutes for the usual gate dielectric. It is separated from the semiconductor material of the channel region 2 and from the electrically conductive gate electrode 3 by a lower boundary layer 5 and an upper boundary layer 6. The boundary layers are also dielectric material. The charge-trapping layer 4 can be silicon nitride, and the boundary layers silicon oxide. The operating method does not depend in principal on the materials that are provided for the charge-trapping layer sequence, but may be modified accordingly.

The transistor structure of the memory cell is completed by a source region 7 and a drain region 8, which are formed by doped regions in the semiconductor material. The semiconductor substrate 1 is preferably provided with a basic doping or intrinsic doping so that the boundaries of the source region 7 and the drain region 8 are formed by pn-junctions. The upper margins of the pn-junctions are preferably arranged beneath the lower lateral edges of the gate electrode 3 so that the channel region 2 is completely covered by the gate electrode 3 as shown in FIG. 1.

The arrangement of the channel, the gate electrode, the source/drain regions, and the charge-trapping layer sequence can be modified without departing from the spirit and scope of the invention. It is also possible to arrange the memory cell in a wall of a trench within the semiconductor substrate or in a wall or surface of a ridge of semiconductor material formed on a surface of the substrate or the like.

The device shown in FIG. 1 can be programmed by an injection of hot electrons from the channel. The electrons are accelerated along the channel region 2 by a voltage that is applied between the source region 7 and the drain region 8, negative at source and positive at drain. The electrons acquire sufficient kinetic energy to be able to pass the dielectric lower boundary layer 5 and enter the charge-trapping layer 4. To this purpose, a relatively low positive voltage is applied to the gate electrode 3. The electrons are trapped in the dielectric material of the charge-trapping layer 4 so that the accumulated charge changes the threshold voltage of the transistor structure. This can be detected in a reading process, which simply means that appropriate operating voltages are applied to source, drain and gate of the transistor structure and a current from source to drain through the channel region 2 is measured. This current depends on the voltage that is applied between gate and drain. The necessary threshold voltage is changed by the programming of the memory cell.

FIGS. 2a and 2b, collectively FIG. 2, shows a diagram, in which the distance that is designated in FIG. 1 by the arrow s is represented on the horizontal line. The curves in the diagram show charge density distributions in the charge-trapping layer 4. Every curve in FIG. 2 represents a typical charge distribution in the charge-trapping layer 4 of the memory cell in a programmed state. There are different examples shown in FIGS. 2a and 2b, depending on different embodiments of the memory cell. If the memory cell is programmed by CHE (channel hot electrons), the charge is concentrated at either lateral limit of the charge-trapping layer 4 at position si or S2 (FIG. 2a). The amount of charge can be varied in the programming process. This is also a means to store more than one bit; the levels are distinguished by the different threshold voltages, which depend on the amount of stored charge. By the polarity of the accelerating voltage between source and drain, the channel end at which the charge carriers are injected into the charge-trapping layer can be selected.

The memory cell can also be programmed by a tunneling process, usually Fowler-Nordheim tunneling, which is generated by the application of a voltage between the channel region 2 and the gate electrode 3 without an accelerating voltage between source and drain. If electrons from the channel are to pass the lower boundary layer 5 and be trapped in the charge-trapping layer 4, a positive voltage is applied to the gate electrode 3. Since the charge distribution in the channel is symmetric in this case, a symmetric charge accumulation in the charge-trapping layer 4 results, if Fowler-Nordheim tunneling is used. This is represented in FIG. 2b by the four curves that extend all over the distance representing the channel region between s₁ and s₂.

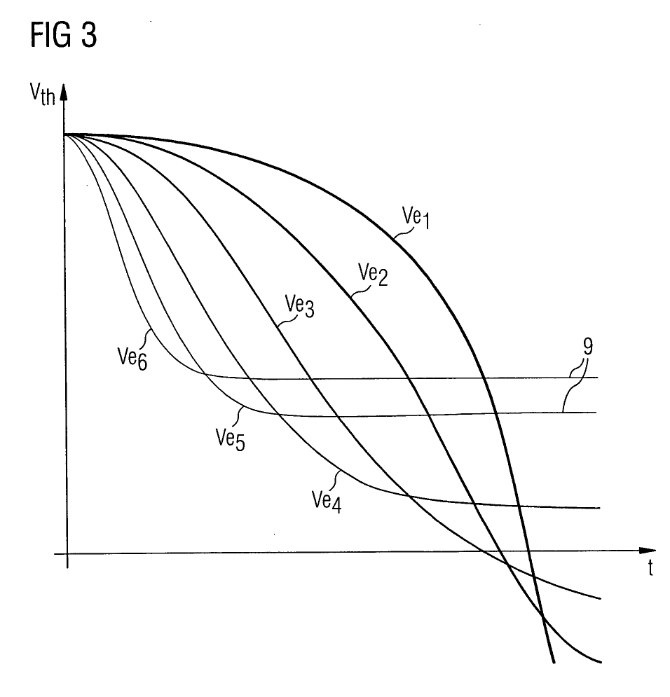

FIG. 3 is a diagram that shows how the threshold voltage of a charge-trapping memory cell varies over time in an erasing process, if an erasing voltage Ve₁, Ve₂, Ve₃, Ve₄, Ve₅ or Ve₆ is applied between the gate electrode and the channel region. The erasing voltages are numbered in the order of their values. The first erasing voltage Ve₁ is for example −9 V, Ve₃ typically −11 V and Ve₄ typically −12 V. At time 0, the programmed memory cell has a certain threshold voltage Vₜₕ. If the memory cell is erased by Fowler-Nordheim tunneling of charge carriers from the channel region into the charge-trapping layer, the threshold voltage changes according to the graphical representation in the diagram of FIG. 3. In the erasing process, an electric potential is applied to the gate electrode, which is typically 10 V to 20 V below, i.e., more negative than, the potential of the channel region. If the stored charge carriers are electrons, a negative voltage with respect to the channel is applied to the gate electrode, in order to attract holes, i.e., positive charge carriers, from the channel through the lower boundary layer 5 into the charge-trapping layer 4, in order to compensate the corresponding amount of negative trapped charge.

If the erasing voltage is in the range that is applied in an erasing process by channel hot holes, the threshold voltage typically changes according to the curves belonging to Ve₁, Ve₂ or Ve₃ in FIG. 3. The diagram shows that the threshold voltage continuously decreases until it reaches negative values. This is a state of overerasure, which is not desired, since it results in very different states of the memory cells that have been erased together. It is not possible to adjust the erasing time to obtain the desired value of the threshold voltage for every erased memory cell, because the memory cells have different threshold voltages depending on their programming state. Therefore, a minimal erasing time that is necessary to obtain a completely erased sector produces a widespread distribution of the resulting threshold voltages.

If the erasing voltage is increased so that a more negative voltage is applied to the gate electrode 3, the curves of the threshold voltage tend to show the characteristic of the curve belonging to Ve₆. In this case, the threshold voltage attains a steady-state value 9. This can be explained by a tunneling of electrons from the gate electrode through the upper boundary layer 6 into the charge-trapping layer 4. This electron current into the charge-trapping layer 4 increases as more and more positive charges compensate the negative trapped charge in the charge-trapping layer 4. Thus, there are two opposite currents: holes moving from the channel upwards into the charge-trapping layer 4 to compensate the negative charge of the trapped electrons; and electrons moving from the gate electrode into the charge-trapping layer 4 due to the negative voltage at the gate electrode 3 and the decreasing negative potential in the charge-trapping layer 4. As a result, the negative charge in the charge-trapping layer 4 cannot be compensated completely, and the memory cell is not erased completely. The resulting threshold voltage lies above a value that corresponds to the memory cell in a state in which the charge-trapping layer 4 is totally void of charge carriers.

The operating method according an embodiment of the present invention makes use of the steady-state value of the threshold voltage, which is achieved if the erasing is performed by a tunneling process of charge carriers and not by an injection of hot charge carriers at a lower voltage between the gate electrode and the channel region. The use of a higher voltage at the gate electrode not only results in the appearance of a lower boundary of the threshold voltage, but has the advantage of an increased erasing speed. Furthermore, the lower boundary layer can be made thick enough, typically at least 3 nm, to guarantee a good data retention. The large voltage between the gate electrode and the channel region enables an erasure by a tunneling process in spite of the relatively thick lower boundary layer.

The charge carriers that tunnel from the gate electrode into the dielectric material have to pass a potential barrier between the electrically conductive material of the gate electrode and the dielectric material. The barrier height depends on the material of the gate electrode and should be high enough to keep the amount of tunneling charge small. Especially preferred materials of the gate electrode are highly p-doped polysilicon, titanium nitride, and tantalum nitride.

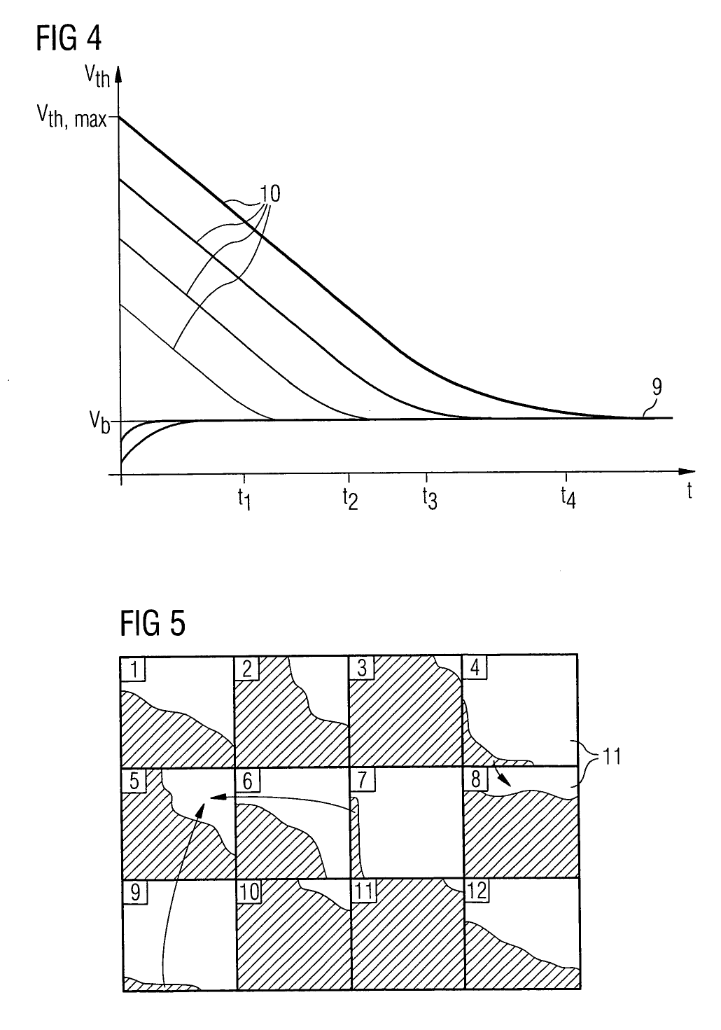

FIG. 4 shows a diagram of the threshold voltage over the erasing time for several different initial values. It is supposed that a sufficiently negative voltage with respect to the channel is applied to the gate electrode in order to provide the steady-state value 9 of the threshold voltage, which is reached after a sufficient duration of the erasing process. The steady-state value 9 corresponds to a lower boundary value V_{b} of the threshold voltage, which is the same for all memory cells of the erased sector, independently of the initial value 10. The diagram of FIG. 4 is idealized, but shows in principal how the method works. It further shows that the steady-state value 9 is also reached by those memory cells which initially have a threshold voltage below the steady-state value 9, for example, because they have not yet been programmed at all and are consequently still void of trapped charges.

Starting from the lowest represented initial value 10 of the threshold voltage above the lower boundary value V_{b}, a steady state is obtained after the time to. Memory cells with a larger initial threshold voltage require a longer erasing time until the steady-state value 9 is attained at times t₂, t₃, and t₄, respectively. According to the use of the memory cell as a single-bit or a multi-bit memory cell, there is a maximal value of the threshold voltage V_{th,max} which can occur in any of the memory cells. Therefore, the maximal value of the threshold voltage determines the minimal time that is necessary to bring the threshold voltages of every memory cell of the sector that is to be erased to the level of the lower boundary value V_{b}.

It may be sufficient, if the lower boundary value is approached within a certain percentage, preferably about 5 percent of the total range between the maximal value of the threshold voltage and the lower boundary value V_{b}. Instead, the erasure can be effected until the rate of change of the value of the threshold voltage per unit time has decreased to one tenth of an initial value of this rate of change. The value of the threshold voltage does not attain the lower limit instantaneously, but rather asymptotically. But this is no impediment to the application of this operating method.

The operating method according to an embodiment of this invention is especially suited to extremely large memories with huge storage capacity. The erasure of such memories takes place for all the memory cells within the same sector in common. The erasure can be performed irrespective of the different programming states of the individual memory cells within the sector that is to be erased. This is a major advantage in comparison to erasing procedures that take account of the different threshold voltages, for example by a preprogramming of all the memory cells that are not already in a programmed state. Especially with very large memories such a procedure increases the erasing time considerably. Therefore, the operating method according to embodiments of this invention is appropriate to reduce the erasing time essentially, although the individual erasing process by the tunneling of charge carriers takes more time than an injection of hot charge carriers.

This method can be applied regardless of the programming state of individual memory cells and without distinction between programmed and non-programmed memory cells. Even the memory cells that initially have a lower threshold voltage are brought to the steady-state value. Thus, this method produces an erased sector of memory cells with threshold voltages that lie all within a very small range of tolerances.

The method has particular application to memory cell arrays that have a minimum feature size of less than 70 nm. The minimum feature size here designates the half pitch of the narrowest parallel arrangement of electric conductors that are provided on the substrate to address the memory cells, in other words the half pitch of the address line level that is shrunk most of all, which may be the level of the wordlines or the first metal level.

The preferred embodiments of the memory device that is operated with this method have dimensions and operating voltages that lie in the following ranges. The value of the voltage that is applied between the gate electrode and the channel region during erase operations preferably lies a) in the range from 12 V to 23 V, more preferably b) in the range from 14 V to 20 V, and even more preferably c) in the range from 15 V to 18 V. The lower boundary layer 5, which is preferably formed of oxide, has a thickness that is adapted both in view of well-known properties of charge-trapping memory cells in general and in view of the operating method according to embodiments of this invention. Thus, the value of the thickness of the lower boundary layer 5 preferably lies in the range from 3 nm to 4.5 nm in case a) above, in the range from 3.2 nm to 4.1 nm in case b) above, and in the range from 3.5 nm to 3.8 nm in case c) above. The total oxide equivalent thickness of the dielectric layer sequence that forms the gate dielectric and comprises the lower boundary layer 5, the charge-trapping layer 4, and the upper boundary layer 6, i.e., the thickness of a single oxide layer that renders the same capacitance per unit area as the layer sequence, is preferably adapted to the thickness of the lower boundary layer, the smallest half pitch of the memory cell array, and the provided operating voltage. The value of the total oxide equivalent thickness of the dielectric layer sequence lies preferably in the range from 10 nm to 15 nm in case a), in the range from 10 nm to 14 nm in case b), and in the range from 11 nm to 13 nm in case c).

A further advantage can be achieved, if the erasing procedure is combined with a special administration of the disposition of the memory sectors. This is explained in connection with FIG. 5, which shows a schematic view of the memory cell array, subdivided into several sectors 11, in this example totally twelve sectors. In the simplified representation, each sector is represented by a square area of the memory cell array and is enumerated with numbers from 1 to 12 that are inserted in the left upper corner. In each sector a hatched area is shown, which designates the area that is occupied by the valid files containing the stored information. It is supposed that the valid files occupy a connected area, the complementary area of each sector containing only invalid files.

In the operation of the memory device, an algorithm is implemented, which takes account of the valid files and invalid files in every sector. If the portion of the storage capacity of a sector that is occupied by valid files has become smaller than a certain portion that is specified in advance, all the valid files of the sector in question are copied into a free space of another sector, preferably a sector that is almost completely filled. In the example shown in FIG. 5, the valid files of sector 4 are copied into sector 8, the valid remnants in sectors 7 and 9 are both copied into sector 5, and sectors 4, 7, and 9 are subsequently erased. This algorithm enables an economic erasing process of whole sectors in common.

The erasing process by means of the tunneling of charge carriers takes a longer time than the erasing by hot holes. Therefore, it is preferable to perform the erasure in the background, while the rest of the memory is operated in the usual way. The erasure of the sectors does not interfere with the programming and reading operations in the other sectors. This operating method, preferably together with the described algorithm, is, therefore, especially appropriate for very large memories. This makes charge-trapping memories the first choice for the design of future memory applications, especially in connection with chip cards or other storage media that are provided to offer huge amounts of information in a handy and easily disposable format.

Although the present invention and its advantages have been described in detail, it should be understood that various changes, substitutions and alterations can be made herein without departing from the spirit and scope of the invention as defined by the appended claims.

What is claimed is:

1. A method of changing the threshold voltage of a charge-trapping device comprising at least a channel region, a gate electrode controlling an electric field within the channel region and a charge-trapping layer between the channel region and the gate electrode, the method comprising:
applying a voltage between the gate electrode and the channel region to cause a first current of a first kind of charge carriers from the channel region to move into the charge-trapping layer and to cause a second current of a second kind of charge carriers from the gate electrode to move into the charge-trapping layer; and
causing the second current to stop when the value of the second current is at least half the amount of the first current value.

2. The method according to claim 1, wherein the gate electrode comprises highly p-doped polysilicon.

3. The method according to claim 1, wherein the gate electrode comprises titanium nitride.

4. The method according to claim 1, wherein the gate electrode comprises tantalum nitride.

5. The method according to claim 1, wherein the charge-trapping device further comprises a boundary layer of dielectric material between the channel region and the charge-trapping layer, the boundary layer comprising a thickness in the range of about 3 nm to 4.5 nm.

6. The method according to claim 5, wherein applying a voltage comprises applying a voltage between the channel region and the gate electrode comprising a value in the range of about 12 V to 23 V.

7. The method according to claim 5, wherein the charge-trapping device comprises a layer sequence of dielectric materials between the channel region and the gate electrode, the layer sequence comprising a total oxide equivalent thickness in the range of about 10 nm to 15 nm.

8. The method according to claim 1, wherein the charge-trapping device further comprises a boundary layer of dielectric material between the channel region and the charge-trapping layer, the boundary layer comprising a thickness in the range of about 3.2 nm to 4.1 nm.

9. The method according to claim 8, wherein applying a voltage comprises applying a voltage between the channel region and the gate electrode comprising a value in the range of about 14 V to 20 V.

10. The method according to claim 8, wherein the charge-trapping device comprises a layer sequence of dielectric materials between the channel region and the gate electrode, the layer sequence comprising a total oxide equivalent thickness in the range of about 10 nm to 14 nm.

11. The method according to claim 1, wherein the charge-trapping device further comprises a boundary layer of dielectric material between the channel region and the charge-trapping layer, the boundary layer comprising a thickness in the range of about 3.5 nm to 3.8 nm.

12. The method according to claim 11, wherein applying a voltage comprises applying a voltage between the channel region and the gate electrode comprising a value in the range of about 15 V to 18 V.

13. The method according to claim 11, wherein the charge-trapping device comprises a layer sequence of dielectric materials between the channel region and the gate electrode, the layer sequence comprising a total oxide equivalent thickness in the range of about 11 nm to 13 nm.

14. The method according to claim 1, further comprising changing a threshold voltage to approach a steady-state value within a range that is specified for an erased state.

15. The method according to claim 1, wherein applying a voltage comprises applying the voltage between the gate electrode and the channel region during a time interval of between about 1 ms and 1 s.

16. A method of changing threshold voltages of a plurality of charge-trapping memory cells each comprising at least a channel region, a gate electrode controlling an electric field within the channel region and a charge-trapping layer between the channel region and the gate electrode, the method comprising:
simultaneously applying a voltage to the memory cells between each gate electrode and the channel region to cause a first current of a first kind of charge carriers from the channel region to move into the charge-trapping layer and to cause a second current of a second kind of charge carriers from the gate electrode to move into the charge-trapping layer; and
causing the second current to stop when the values of the second current of the memory cells are at least half the amount of the corresponding first current values.

17. The method according to claim 16, further comprising:
providing at least one sector of the memory cells;
specifying a fraction of the sector in advance;
keeping record of invalid files of the sector; and
if more than the fraction is occupied by invalid files, copying other files of the sector into another sector and erasing the former sector.

18. A semiconductor memory device, comprising:
a channel region;
a gate electrode adjacent the channel region;
a charge-trapping layer between the channel region and the gate electrode; and
operating circuitry providing a voltage between the gate electrode and the channel region, the voltage being selected to cause a first current of a first kind of charge carriers from the channel region to move into the charge-trapping layer and to cause a second current of a second kind of charge carriers from the gate electrode to move into the charge-trapping layer, until the value of the second current is at least half the amount of the first current value.

19. The semiconductor memory device according to claim 18, wherein the operating circuitry is integrated in on a single semiconductor substrate with the channel region, the gate electrode and the charge-trapping layer.

20. The semiconductor memory device according to claim 18, wherein the gate electrode comprises highly p-doped polysilicon.

21. The semiconductor memory device according to claim 18, wherein the gate electrode comprises titanium nitride.

22. The semiconductor memory device according to claim 18, wherein the gate electrode comprises tantalum nitride.

23. The semiconductor memory device according to claim 18, further comprising a boundary layer of dielectric material located between the channel region and the charge-trapping layer, the boundary layer comprising a thickness in the range of about 3 nm to 4.5 nm.

24. The semiconductor memory device according to claim 23, wherein the voltage between the channel region and the gate electrode has a value in the range of about 12 V to 23 V.

25. The semiconductor memory device according to claim 23, wherein the device includes a layer sequence of dielectric materials located between the channel region and the gate electrode, the layer sequence comprising a total oxide equivalent thickness in the range of about 10 nm to 15 nm.

26. The semiconductor memory device according to claim 18, further comprising a boundary layer of dielectric material located between the channel region and the charge-trapping layer, wherein the thickness of the boundary layer is in the range of about 3.2 nm to 4.1 nm.

27. The semiconductor memory device according to claim 26, wherein the voltage between the channel region and the gate electrode has a value in the range of about 14 V to 20 V.

28. The semiconductor memory device according to claim 26, wherein the device includes a layer sequence of dielectric materials located between the channel region and the gate electrode, the layer sequence comprising a total oxide equivalent thickness in the range of about 10 nm to 14 nm.

29. The semiconductor memory device according to claim 18, further comprising a boundary layer of dielectric material located between the channel region and the charge-trapping layer, the boundary layer comprising a thickness in the range of about 3.5 nm to 3.8 nm.

30. The semiconductor memory device according to claim 29, wherein the voltage between the channel region and the gate electrode has a value in the range of about 15 V to 18 V.

31. The semiconductor memory device according to claim 29, wherein the memory device includes a layer sequence of dielectric materials located between the channel region and the gate electrode, wherein the total oxide equivalent thickness of the layer sequence is in the range of about 11 nm to 13 nm.

32. A semiconductor memory device, comprising:
an array of memory cells;
each memory cell comprising a channel region, a gate electrode adjacent the channel region, and a charge-trapping layer between the channel region and the gate electrode; and
operating circuitry providing a voltage between the gate electrode and the channel region of a plurality of the memory cells, the voltage being selected to cause a first current of a first kind of charge carriers from the channel region to move into the charge-trapping layer and to cause a second current of a second kind of charge carriers from the gate electrode to move into the charge-trapping layer, until the values of the second current of the memory cells of the plurality are at least half the amount of the corresponding first current values.

33. The semiconductor memory device according to claim 32, wherein the operating circuitry is integrated on a single semiconductor substrate with the array of memory cells.

34. A semiconductor memory device, comprising:
an array of memory cells;
each memory cell comprising a channel region, a gate electrode adjacent the channel region, and a charge-trapping layer between the channel region and the gate electrode; and
means for applying a voltage between the gate electrode and the channel region to cause a first current of a first kind of charge carriers from the channel region to move into the charge-trapping layer and to cause a second current of a second kind of charge carriers from the gate electrode to move into the charge-trapping layer; and
means for causing the second current to stop when the value of the second current is at least half the amount of the first current value.

35. The semiconductor device according to claim 34, wherein the means for applying the voltage and the means for causing the second current to stop are integrated on a single semiconductor substrate with the array of memory cells.
